(19) United States
(12) Patent Application Publication
(10) Pub. No.: US 2024/0071473 A1
(43) Pub. Date: Feb. 29, 2024

(54) MICROELECTRONIC DEVICES INCLUDING CONTROL LOGIC CIRCUITRY OVERLYING MEMORY ARRAYS, AND RELATED MEMORY DEVICES AND ELECTRONIC SYSTEMS

(71) Applicant: Micron Technology, Inc., Boise, ID (US)

(72) Inventors: Yuan He, Boise, ID (US); Fatma Arzum Simsek-Ege, Boise, ID (US)

(21) Appl. No.: 17/898,150

(22) Filed: Aug. 29, 2022

(51) Int. Cl. G11C 11/4091; G11C 11/408

(52) U.S. Cl. CPC G11C 11/4091; G11C 11/4085

(57) ABSTRACT

A microelectronic device is disclosed that incudes array regions individually comprising memory cells comprising access devices and storage node devices; digit lines coupled to the access devices that extend in a first direction; and word lines coupled to the access devices that extend in a second direction orthogonal to the first direction. Digit line exit regions horizontally alternate with the array regions in the first direction; sense amplifier sections comprising sense amplifier circuitry vertically overlie and horizontally overlapping the digit line exit regions; and routing structures within horizontal areas of the digit line exit regions, couple the sense amplifier circuitry of the sense amplifier sections to the digit lines.

### TECHNICAL FIELD

The disclosure, in various embodiments, relates generally to the field of microelectronic device design. More specifically, the disclosure relates microelectronic devices including control logic circuitry overlying memory arrays, and to related memory devices, and electronic systems.

### BACKGROUND

Microelectronic devices often have complex signal routing that may affect performance. One example of a microelectronic device is a memory device. Memory devices are generally provided as internal integrated circuits in computers or other electronic devices. There are many types of memory devices including, but not limited to, volatile memory devices. One type of volatile memory device is a dynamic random access memory (DRAM) device. A DRAM device may include a memory array including DRAM cells arranged in rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit lines and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit lines and word lines coupled to the DRAM cells by way of structures (e.g., vertical routing structures, such as conductive contacts; horizontal routing structures). Unfortunately, three-dimensional (3D) memory device (e.g., 3D DRAM device) architectures can require complex and congested routing designs to electrically connect DRAM cells to control logic circuitry, such as sub word line drivers (SWD) circuitry and sense amplifiers (SA) circuitry.

### BRIEF DESCRIPTION OF THE DRAWINGS

FIG. 1 is a simplified plan view of a microelectronic device, in accordance with an embodiment of the disclosure.

FIG. 2A is a simplified plan view of a portion of the microelectronic device depicted in FIG. 1 with additional details for digit line exit regions and digit line layouts.

FIG. 2B is a simplified plan view of a portion of the microelectronic device depicted in FIG. 2A with additional details for control logic devices.

FIG. 3A is a simplified, partial longitudinal cross-sectional view of a digit line exit region of the microelectronic device depicted in FIG. 1.

FIG. 3B is a simplified, partial longitudinal cross-sectional view of a word line exit region of the microelectronic device depicted in FIG. 1.

FIG. 4 is a schematic diagram of connections between a word line and digit lines in a two-transistor, two capacitor configuration.

FIG. 5 is a block diagram of an electronic system, according to embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round or curved may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnxO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “integrated circuit” or “integrated-circuit device” may refer to a “microelectronic device” or a “nanoelectronic device,” each of which may be tied to a critical dimension exhibited by inspection. The term “integrated circuit” includes without limitation a memory device, as well as other devices (e.g., semiconductor devices) which may or may not incorporate memory. The term “integrated circuit” may include without limitation a logic device. The term “integrated circuit” may include without limitation a processor device such as a central-processing unit (CPU) or a graphics-processing unit (GPU). The term “integrated circuit” may include without limitation or a radiofrequency (RF) device. Further, an “integrated-circuit” device may incorporate memory in addition to other functions such as, for example, a so-called “system on a chip” (SoC) including a processor and memory, or an integrated-circuit device including logic and memory. Further, an “integrated-circuit” device may incorporate memory in addition to other functions such as, for example, a so-called “disaggregated device” where distinct integrated-circuit components are associated to produce the higher function such as that performed by an SoC, including a processor alone, a memory alone, a processor and a memory, or an integrated-circuit device including logic and memory.

As used herein, the term “substrate” means and includes a material (e.g., a base material) or construction upon which additional materials are formed. The substrate may be a semiconductor substrate. The substrate may be a base semiconductor material on a supporting structure, a metal electrode, or a semiconductor substrate having one or more materials, layers, structures, or regions formed thereon. The materials on the semiconductor substrate may include, but are not limited to, one or more of semiconductor materials, insulating materials, and conductive materials. The substrate may be a conventional silicon substrate or other bulk substrate comprising a layer of semiconductor material. As used herein, the term “bulk substrate” means and includes not only silicon wafers, but also silicon-on-insulator (“SOI”) substrates. The “bulk substrate” may be a SOI substrate such as a silicon-on-sapphire (“SOS”) substrate. The “bulk substrate” may be a SOI substrate such as a silicon-on-glass (“SOG”) substrate. The “bulk substrate” may include epitaxial layers of silicon on a base semiconductor foundation. The “bulk substrate” may include other semiconductor and/or optoelectronic materials. The semiconductor and/or optoelectronic materials may, for example, include one or more of silicon-germanium containing materials, germanium-containing materials, silicon-carbide containing materials, gallium arsenide-containing materials, gallium nitride-containing materials, and indium phosphide-containing materials. The substrate may be doped or undoped.

As used herein, the term “mounting substrate” means and includes structures that are configured to accept an integrated-circuit device. The mounting substrate may be a silicon bridge that is configured to connect more than on integrated-circuit device. The mounting substrate may be a package board that directly contacts an integrated circuit device such as a bare die containing a central-processing unit. The package board may be mounted on a printed wiring board (PWB). The mounting substrate may be a printed wiring board onto which at least one integrated circuit device and/or package board are mounted. The mounting substrate may include a disaggregated device.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

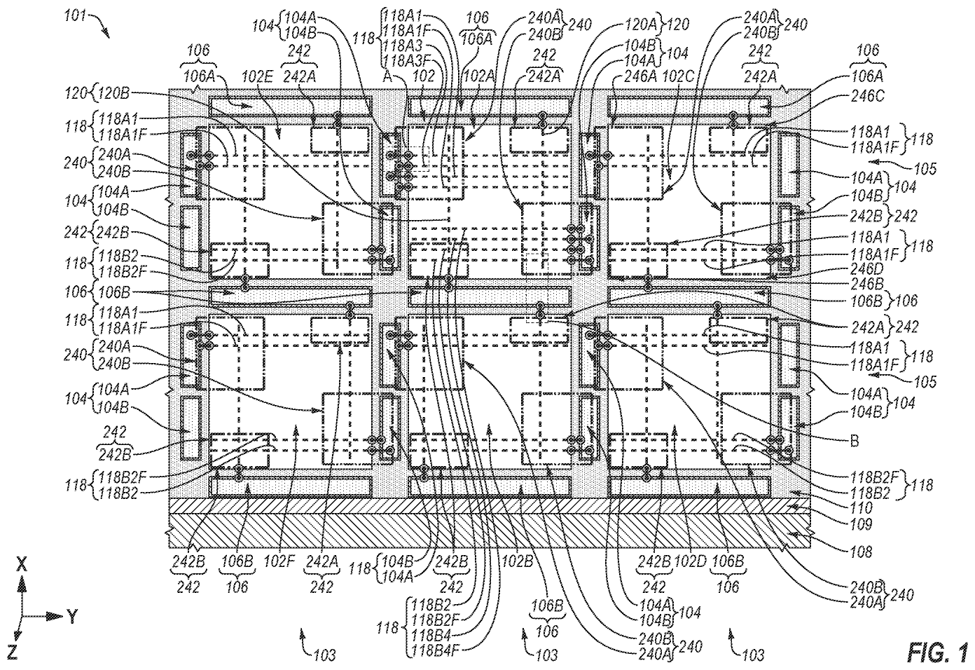

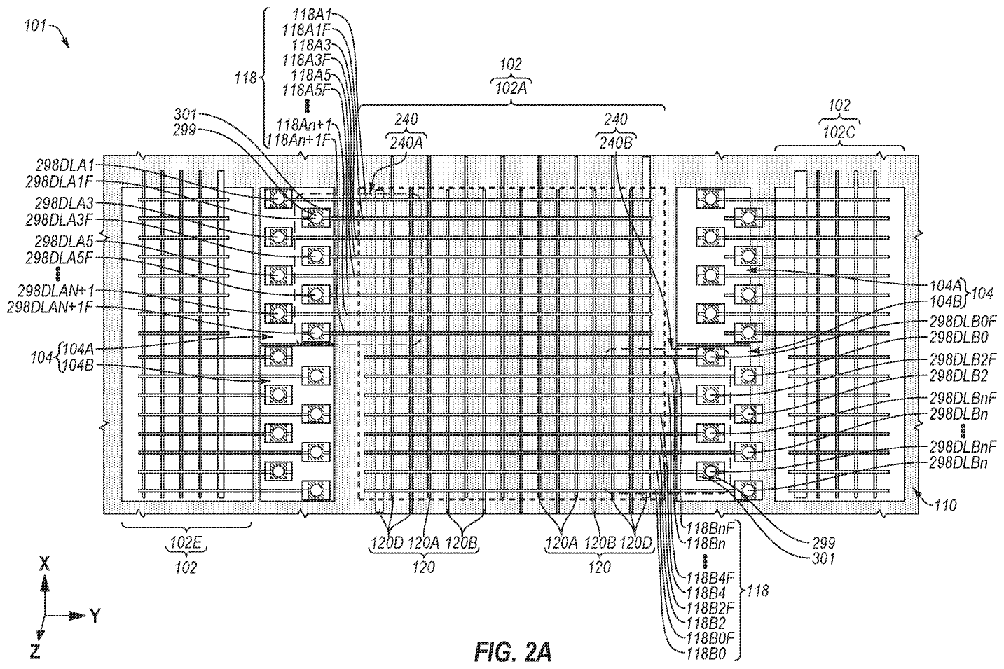

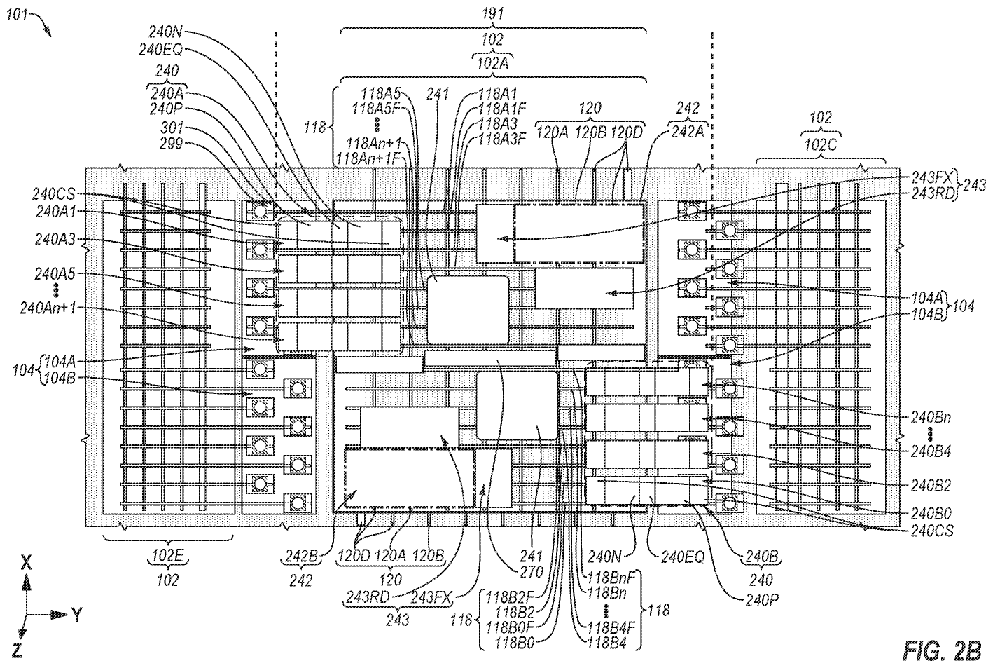

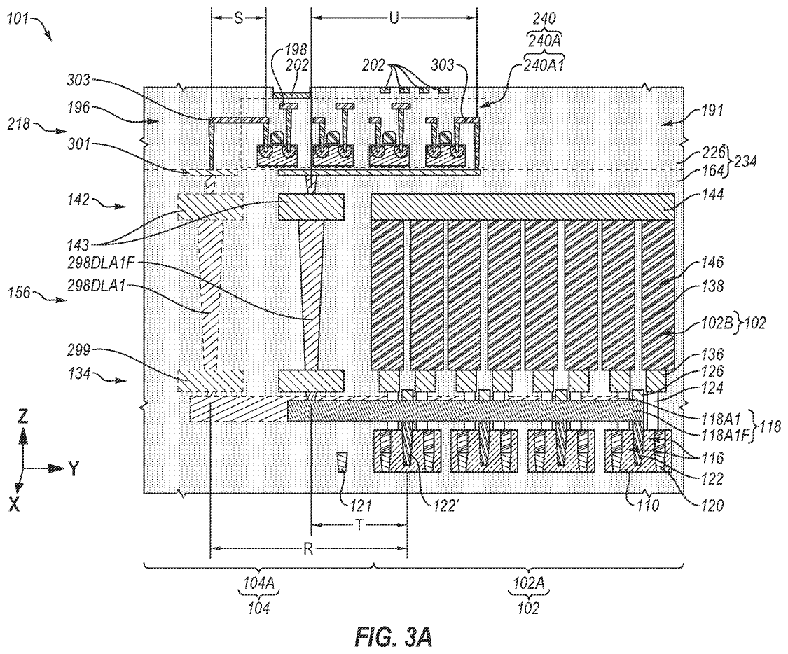

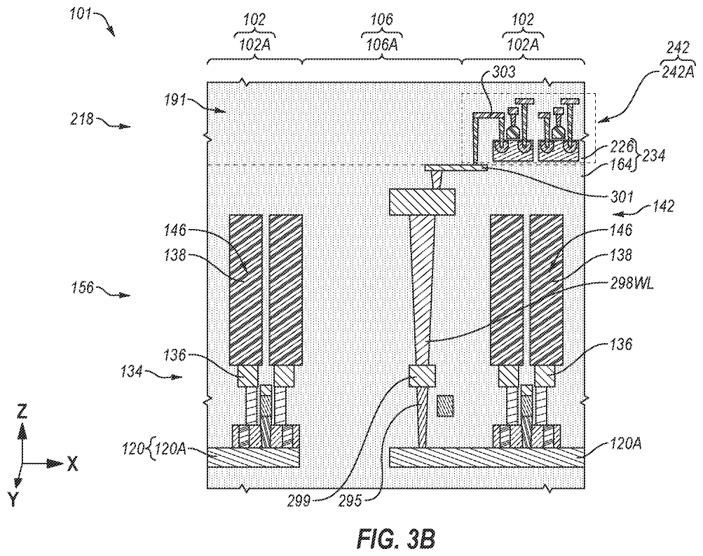

FIG. 1 is a simplified plan view of a microelectronic device 101 (e.g., a memory device, such as a 3D DRAM device), in accordance with embodiments of the disclosure. FIGS. 2A and 2B are simplified plan views of a portion of the microelectronic device 101 depicted in FIG. 1 with additional details for digit line exit regions and digit line layouts (FIG. 2A) and with additional details for control logic devices (FIG. 2B). FIGS. 3A and 3B are transverse cross-section elevational views of the microelectronic device 101, where a memory array device assembly 156 is mated to a CMOS device structure 218.

Referring collectively to FIGS. 1, 3A, and 3B, the microelectronic device 101 includes a memory array device assembly 156 (also referred to as a first microelectronic device structure 156) (FIGS. 3A and 3B) and in the CMOS device structure 218 (also referred to as a second microelectronic device structure 218) (FIGS. 3A and 3B). The microelectronic device 101 further includes array regions 102, digit line exit regions 104 (also referred to as “digit line contact socket regions”) interposed between pairs of the array regions 102 horizontally neighboring one another in a first horizontal direction (e.g., the Y-direction), word line exit regions 106 (also referred to as “word line contact socket regions”) interposed between additional pairs of the array regions 102 horizontally neighboring one another in a second horizontal direction (e.g., the X-direction) orthogonal to the first horizontal direction, and one or more socket regions 108 (also referred to as “back end of line (BEOL) contact socket regions”) horizontally neighboring some of the array regions 102 in one or more of the first horizontal direction and the second horizontal direction. The microelectronic device 101 may also include control logic regions 109, as well as routing arrangements to different control logic devices (e.g., corresponding to control logic devices 191 (FIGS. 2B and 3A)) within the different control logic sections, in accordance with embodiments of the disclosure. The array regions 102, the digit line exit regions 104, the word line exit regions 106, the socket regions 108, the control logic devices 191, and the control logic regions 109, are each described in further detail below.

The array regions 102 of the microelectronic device 101 may comprise horizontal areas of the microelectronic device 101 configured and positioned to have arrays of memory cells (e.g., arrays of DRAM cells) within horizontal areas thereof, as described in further detail below. In addition, the array regions 102 may also be configured and positioned to have desirable arrangements of control logic devices at least partially within horizontal boundaries thereof, as also described in further detail below. The control logic devices 191 (FIGS. 2B, 3A, and 3B) are at least partially within the horizontal areas of the array regions 102 and may be vertically offset (e.g., in the Z-direction) from the memory cells within the horizontal areas of the array regions 102.

The microelectronic device 101 may include a desired quantity of the array regions 102. For clarity and ease of understanding of the drawings and related description, FIG. 1 depicts the microelectronic device 101 to include six (6) array regions 102; a first array region 102A, a second array region 102B, a third array region 102C, a fourth array region 102D, a fifth array region 102E, and a sixth array region 102F. The array regions 102 include DRAM array devices as set forth herein. As shown in FIG. 1, the third array region 102C may horizontally neighbor the first array region 102A in a first direction (Y-direction), and the first array region 102A may also horizontally neighbor the fifth array region 102E in the first direction opposite the third array region 102C. The first array region 102A may also horizontally neighbor the second array region 102B in a second direction (X-direction) that is substantially orthogonal to the first direction. As also shown in FIG. 1, the second array region 102B may horizontally neighbor the fourth array region 102D in the first direction, and the second array region 102B may also horizontally neighbor the sixth array region 102F in the first direction opposite the fourth array region 102D. In additional embodiments, the microelectronic device 101 includes a different number of array regions 102. For example, the microelectronic device 101 may include greater than six (6) array regions 102 as illustrated, such as greater than or equal to eight (8) array regions 102, greater than or equal to sixteen (16) array regions 102, greater than or equal to thirty-two (32) array regions 102, greater than or equal to sixty-four (64) array regions 102, greater than or equal to one hundred twenty eight (128) array regions 102, greater than or equal to two hundred fifty six (256) array regions 102, greater than or equal to five hundred twelve (512) array regions 102, or greater than or equal to one thousand twenty-four (1024) array regions 102.

In addition, the microelectronic device 101 may include a desired distribution of the array regions 102. As shown in FIG. 1, in some embodiments, the microelectronic device 101 includes rows 103 of the array regions 102 extending in the X-direction, and columns 105 of the array regions 102 extending in the Y-direction. The rows 103 of the array regions 102 may, for example, include a first row 103 including the first array region 102A and the second array region 102B, a second row 103 including the third array region 102C and the fourth array region 102D, and a third row 103 including the fifth array region 102E and the sixth array region 102F. The columns 105 of the array regions 102 may, for example, include a first column 105 including the first array region 102A, the third array region 102C, and the fifth array region 102E, and a second column 105 including the second array region 102B, the fourth array region 102D, and the sixth array region 102F.

With reference to FIG. 1, the digit line exit regions 104 of the microelectronic device 101 may comprise horizontal areas of the microelectronic device 101 configured and positioned to have at least some digit lines 118 (e.g., bit lines, data lines) horizontally terminate (e.g., in the Y-direction) therein. The digit lines 118 may be positioned vertically below (e.g., in the Z-direction) memory cells 146 (FIG. 3A) within the array regions 102, and may horizontally extend in the first direction (e.g., the Y-direction). For an individual digit line exit region 104, at least some digit lines 118 operatively associated with the array regions 102 flanking (e.g., at opposing horizontal boundaries in the Y-direction) the digit line exit region 104 may have ends within the horizontal area of the digit line exit region 104. In addition, the digit line exit regions 104 may also be configured and positioned to include contact structures and routing structures with the horizontal areas thereof that are operatively associated with at least some of the digit lines 118. As described in further detail below, some of the contact structures within the digit line exit regions 104 may couple the digit lines 118 to control logic circuitry of control logic devices 191 (e.g., CMOS circuitry sub region sense amplifier (SA) sections 240) that are above the arrays of memory cells within the array regions 102 in the second microelectronic device structure 218 (e.g., FIGS. 2B and 3A), and the CMOS circuitry sub region SA sections 240 are also at least partially above portions of the digit lines 118 within the digit line exit regions 104. As shown in FIG. 1, in some embodiments, the digit line exit regions 104 horizontally extend in the X-direction, and are horizontally interposed between horizontally neighboring rows 103 of the array regions 102 that extend in the Y-direction. The digit line exit regions 104 may, for example, horizontally alternate with the rows of the array regions 102 in the Y-direction.

An individual digit line exit region 104 may be divided into multiple sub regions. For example, as shown in FIG. 1, an individual digit line exit region 104 may include odd digit line exit sub regions 104A and even digit line exit sub regions 104B. In some embodiments, the odd digit line exit sub regions 104A horizontally alternate with the even digit line exit sub regions 104B in the X-direction. A trio (e.g., three (3)) of horizontally neighboring array regions 102 within an individual column 105 of the array regions 102 may include two (2) of the odd digit line exit sub regions 104A and two (2) of the even digit line exit sub regions 104B positioned horizontally therebetween in the Y-direction: one (1) of the odd digit line exit sub regions 104A and one (1) of the even digit line exit sub regions 104B positioned horizontally between the first array region 102A and the third array region 102C, and one (1) of the odd digit line exit sub regions 104A and one (1) of the even digit line exit sub regions 104B positioned horizontally between the first array region 102A and the fifth array region 102E. By way of non-limiting example, the first array region 102A and the third array region 102C of a first column 105 of the array regions 102 may neighbor one (1) of the odd digit line exit sub regions 104A and one (1) of the even digit line exit sub regions 104B positioned therebetween in the Y-direction.

CMOS circuitry sub region sense amplifier sections 240 may be at least partially (e.g., substantially) positioned vertically above (Z-direction) memory cells 146 (FIG. 3A) within the array regions 102. CMOS circuitry sub region SA sections 240 within a horizontal area of an individual array region 102 include an odd SA sub section 240A and an even SA sub section 240B. The odd SA sub section 240A and the even SA sub section 240B may be horizontally positioned at or proximate opposite corners (e.g., diagonally opposite corners, or “kitty corner”) of the array region 102 than one another. An individual CMOS circuitry sub region SA section 240 (e.g., an odd SA sub section 240A, an even SA sub section 240B) may horizontally overlap each of a horizontal area of an individual array region 102 and a horizontal area of an individual digit line exit region 104. Odd sense amplifier sub sections 240A may horizontally extend into the odd digit line exit sub regions 104A between the neighboring array regions 102, and even sense amplifier sub sections 240B may horizontally extend into the even digit line exit sub regions 104B between other neighboring array regions 102. As a non-limiting example, with respect to the third array region 102C shown in FIG. 1, the odd sense amplifier sub section 240A and the even sense amplifier sub section 240B horizontally overlapping the first array region 102A may be arranged “kitty corner” (e.g., diagonally) relative to one another within the horizontal area of the third array region 102C. For example, the odd SA sub section 240A may be positioned at or proximate a first corner 246A of the third array region 102C; and the even SA sub section 240B may be positioned at or proximate a fourth corner 246D of the third array region 102C, kitty corner to the first corner 246A of the third array region 102C. In addition, the odd sense amplifier sub section 240A horizontally overlapping the third array region 102C may horizontally extend into an odd digit line exit sub region 104A of a digit line exit region 104 horizontally neighboring the first array region 102A (e.g., proximate the first corner 246A); and the even sense amplifier sub section 240B horizontally overlapping the third array region 102C may horizontally extend into an even digit line exit sub region 104B of another digit line exit region 104 horizontally opposite and distant the first array region 102A (e.g., proximate the fourth corner 246D). As shown in FIG. 1, each of the array regions 102 (e.g., the third array region 102C) also includes a second corner 246B aligned with the first corner 246A thereof in the Y-direction, and aligned with the fourth corner 246D thereof in the X-direction; and a third corner 246C kitty corner to the second corner 246B thereof, aligned with the first corner 246A thereof in the X-direction, and aligned with the fourth corner 246D thereof in the Y-direction.

As described in further detail below, a “closed memory architecture” for CMOS over array (CoA) may mean, e.g., signals from digit lines 118 within a horizontal area of an individual array region 102, are processed within a CMOS circuitry sub region sense amplifier section 240 vertically overlying the array of memory cells of the array region 102. For example for the first array region 102A, an individual odd digit line exit sub region 104A (between the first array region 102A and the fifth array region 102E) may be configured and positioned to facilitate electrical connections between a group of first and third odd digit lines (e.g., first and third odd digit lines 118A1 and 118A3, respectively, and first and third odd comparative digit lines 118A1F and 118A3F, respectively), and a group of control logic devices (e.g., odd CMOS circuitry sub region SA sub sections 240A) at least partially vertically above (Z-direction) an array or memory cells within first array region 102A. The comparative digit lines, e.g., the first odd comparative digit line 118A1F may also be referred to as a “first reference odd digit line” or as a “first false odd digit line.” Similarly, for example for the first array region 102A, an individual even digit line exit sub region 104B (between the first array region 102A and the third array region 102C) may be configured and positioned to facilitate electrical connections between a group of second and fourth even digit lines (e.g., second and fourth even digit lines 118B2 and 118B4, respectively, and second and fourth comparative even digit lines 118B2F and 118B4F, respectively), and a group of control logic devices (e.g., even CMOS circuitry sub region SA sub sections 240B) at least partially vertically above (Z-direction) the array of memory cells within the first array region 102A. The odd sense amplifier sub section 240A and the even sense amplifier sub section 240B horizontally overlapping a horizontal area of an individual array region 102 may individually be operatively associated with a portion (e.g., a half portion in the X-direction) of the array region 102. For example, an odd sense amplifier sub section 240A may vertically overlie and horizontally overlap the first array region 102A and the odd digit line exit sub region 104A horizontally neighboring the first array region 102A, an even sense amplifier sub section 240B may vertically overlie and horizontally overlap the first array region 102A and the even digit line exit sub region 104B horizontally neighboring the first array region 102A, and the odd sense amplifier sub section 240A and the even sense amplifier sub section 240B may operate on reading data in a closed configuration with respect to only the first array region 102A.

Still referring to FIG. 1, attention is directed to the odd digit lines 118A. A first odd digit line 118A1 and a first odd comparative digit line 118A1F are paired and each is coupled to a single (e.g., only one) row of storage node devices 138 (e.g., FIG. 3A), and hence a single row of memory cells 146 (e.g., FIG. 3A) including the storage node devices 138. The first odd digit line 118A1 and the first odd comparative digit line 118A1F are electrically coupled to sense amplifiers of a single (e.g., only one) odd CMOS circuitry sub region SA sub section 240A (e.g., FIG. 3A). Further, a third odd digit line 118A3 and a third odd comparative digit line 118A3F are also electrically coupled to sense amplifier sections of a single CMOS circuitry sub region odd SA sub section 240A. Similarly, a second even digit line 118B2 and a second comparative even digit line 118B2F are paired and each is coupled to a single (e.g., only one) row of storage node devices 138 (e.g., FIG. 3A), and hence a single row of memory cells 146 (e.g., FIG. 3A) including the storage node devices 138. The second even digit line 118B2 and the second comparative even digit line 118B2F are electrically coupled to sense amplifiers of a single (e.g., only one) even CMOS circuitry sub region SA sub section 240B. Further, a fourth even digit line 118B4 and a fourth comparative even digit line 118B4F are also electrically coupled to sense amplifiers of a single even CMOS circuitry sub region SA sub section 240B.

Still referring to FIG. 1 and the first array region 102A, the odd sense amplifier sub section 240A extends in the first direction (e.g., the Y-direction) past first horizontal boundaries of the first array region 102A and into the odd digit line exit sub region 104A between the first array region 102A and the fifth array region 102E. In addition, the even sense amplifier sub section 240B extends in the first direction (e.g., the Y-direction) past second horizontal boundaries the first array region 102A opposing the first horizontal boundaries and into the even digit line exit sub region 104B between the first array region 102A and the third array region 102C. The digit line exit regions 104 may be configured and positioned to include contact structures and routing structures within the horizontal areas thereof that are operatively associated with the digit lines 118. As described in further detail below, some of the contact structures within the digit line exit regions 104 may couple the digit lines 118 to control logic circuitry of additional control logic devices (e.g., sense amplifiers) positioned in the CMOS device structure 218 (e.g., FIGS. 3A and 3B) and at least partially within horizontal areas of the digit line exit regions 104.

Still referring to FIG. 1, the word line exit regions 106 of the microelectronic device 101 may comprise horizontal areas of the microelectronic device 101 configured and positioned to have at least some word lines 120 (e.g., access lines) horizontally terminate therein. The word lines 120 may be partitioned vertically below storage node devices 138 (e.g., FIG. 3A) of memory cells 146 (FIG. 3A) within the array regions 102, and may horizontally extend in the second direction (e.g., the X-direction). The word line exit regions 106 may be configured and positioned to include contact structures and routing structures within the horizontal areas thereof that are operatively associated with the word lines 120. As described in further detail below, some of the contact structures within the word line exit regions 106 may couple the word lines 120 to control logic circuitry of additional control logic devices (e.g., main word line driver and sub-word line driver (SWD) devices) that are positioned in the CMOS device structure 218 (e.g., FIGS. 2B and 3B). The word line exit regions 106 may, for example, horizontally alternate with the columns 105 of the array regions 102 in the X-direction, as odd word line exit regions 106A and even word line exit regions 106B. The odd word line exit regions 106A may horizontally overlap and be operatively associated with odd sub word line driver sections 242A; and the even word line exit regions 106B may horizontally overlap and be operatively associated with even sub word line driver sections 242B. The odd word lines 120A may extend (e.g., in the X-direction) past third horizontal boundaries of the array regions 102 and into odd word line exit regions 106A, and may be coupled to SWD devices of the odd sub word line driver sections 242A. The even word lines 120B may extend (e.g., in the X-direction) past fourth horizontal boundaries of the array regions 102 opposing the third horizontal boundaries into even word line exit regions 106B, and may be coupled to SWD devices of the even sub word line driver sections 242B.

With continued reference to FIG. 1, the socket regions 108 of the microelectronic device 101 may comprise horizontal areas of the microelectronic device 101 configured and positioned to facilitate electrical connections (e.g., by way of contact structures and routing structures formed within horizontal boundaries thereof) between the control logic region 109 and additional structures (e.g., back-end-of-line (BEOL) structures), as described in further detail below. The socket regions 108 may horizontally neighbor one or more peripheral horizontal boundaries (e.g., in the Y-direction, in the X-direction) of one or more groups of the array regions 102. For clarity and ease of understanding of the drawings and related description, FIG. 1 depicts the microelectronic device 101 to include one (1) socket region 108 horizontally neighboring a shared horizontal boundary of a control logic region 109, which is horizontally neighboring a shared horizontal boundary of the second array region 102B and the fourth array region 102D. However, the microelectronic device 101 may be formed to include one or more of a different quantity and a different horizontal position of socket region(s) 108 and control logic region(s) 109. As a non-limiting example, the socket region 108 may horizontally neighbor a shared horizontal boundary of a different group of the array regions 102 (e.g., a shared horizontal boundary of the second array region 102B, the fourth array region 102D, and the sixth array region 102F; a shared horizontal boundary of the first array region 102A, the third array region 102C, and the fifth array region 102E; a shared horizontal boundary of the first array region 102A and the third array region 102C; a shared horizontal boundary of the fifth array region 102E and the sixth array region 102F). As another non-limiting example, the microelectronic device 101 may be formed to include multiple (e.g., a plurality of, more than one) socket regions 108 horizontally neighboring different groups of the array regions 102 than one another. In some embodiments, multiple socket regions 108 collectively substantially horizontally surround (e.g., substantially horizontally circumscribe) the array regions 102.

Referring collectively to FIGS. 1, 2B, 3A, and 3B, the second microelectronic device structure assembly 218 (e.g., CMOS device structure, CMOS device wafer, FIGS. 3A and 3B) includes the CMOS circuitry sub region SA sections 240, the SWD sections 242, and the additional control logic devices 191 (e.g., FIGS. 2B, 3A, and 3B). By locating the CMOS circuitry sub region SA sections 240 in the CMOS device structure 218, vertically over the first microelectronic device assembly 156 and at least partially within the horizontal areas of the digit line exit regions 104, more space above the array regions 102 is made available for other circuitry. Consequently, locating the CMOS circuitry sub region SA sections 240 vertically above the first microelectronic device assembly 156 (and, hence, the memory cells 146) (FIG. 3A) and at least partially with horizontal areas of the digit line exit regions 104 facilitates rearranging the positions of various other control logic devices (e.g., SWD devices, SA control-signal conduits 270 (FIG. 2B), main word line driver (MWD) driver devices, column decoder devices, read-write gap devices) within a horizontal area of the array region 102, as desired. By way of non-limiting example, locating the CMOS circuitry sub region SA sections 240 vertically above and at least partially with horizontal areas of the digit line exit regions 104 of the first microelectronic device assembly 156 (FIG. 3A) may facilitate positioning of other devices, such as SWD devices of the SWD sections 242, above and within horizontal areas of the array regions 102 of the first microelectronic device assembly 156 (FIG. 3A). Additionally, timing delays exhibited in a microelectronic device such as the microelectronic device 101, may be shortened relative to conventional configurations. For example, during use and operation, the microelectronic device 101 may have improved row-address-to-column address (tRCD) timing relative to conventional configurations. The positions of the CMOS circuitry sub region SA sections 240 may enhance the routing efficiency and the overall horizontal area efficiency of the microelectronic device 101.

Referring to FIG. 1, the array regions 102 of the microelectronic device 101 are configured and positioned to have arrays of memory cells 146 (FIG. 3A) (e.g., arrays of DRAM cells) positioned within horizontal areas thereof, as described in further detail below. In addition, the array regions 102 (e.g., the first array region 102A, the second array region 102B, the third array region 102C, the fourth array region 102D, the fifth array region 102E and the sixth array region 102F) may also be configured and positioned to have desirable arrangements of control logic devices 191 (FIGS. 2B, 3A, and 3B) positioned within horizontal areas thereof, as also described in further detail below. At least some of the control logic devices 191 (FIGS. 2B, 3A, and 3B) are positioned vertically above the first microelectronic device assembly 156 (and, hence, the memory cells 146) (FIG. 3A) and at least partially within horizontal areas of the array regions 102.

FIGS. 2A and 2B are simplified plan views of portions of the microelectronic device 101 depicted in FIG. 1 with additional details for the digit line exit regions 104 and layouts of digit lines 118, and with additional details for arrangements of control logic devices 191 (FIG. 2B). Referring to FIG. 2A, the first array region 102A is depicted with portions of the third array region 102C and the fifth array region 102E, where the third array region 102C and the fifth array region 102E are laterally truncated in the first direction (Y-direction). Further, digit lines 118 are illustrated, with some odd digit lines 118A being operatively associated with an odd sense amplifier sub section 240A, and with some even digit lines 118B being operatively associated with an even sense amplifier sub section 240B. The digit lines 118 may exhibit horizontally elongate shapes extending in parallel in the Y-direction; and the word lines 120 may exhibit horizontally elongate shapes extending in parallel in the X-direction and orthogonal to the Y-direction. As used herein, the term “parallel” means substantially parallel. The digit lines 118 and the word lines 120 may each individually include conductive material. By way of non-limiting example, the digit lines 118 and the word lines 120 may each individually include one or more of at least one metal, at least one alloy, and at least one conductive metal-containing material (e.g., a conductive metal nitride, a conductive metal silicide, a conductive metal carbide, a conductive metal oxide). In some embodiments, the digit lines 118 and the word lines 120 each individually include one or more of W, Ru, Mo, and titanium nitride (TiN_{y}). Each of the digit lines 118 and each of the word lines 120 may individually be substantially homogeneous, or one or more of the digit lines 118 and/or one or more of the word lines 120 may individually be substantially heterogeneous. In some embodiments, each of the digit lines 118 and each of the word lines 120 are configured to be substantially homogeneous.

In an embodiment, a base semiconductor structure 110 (FIG. 3A) is configured within in the first microelectronic device assembly 156 (FIGS. 3A and 3B) such that a closed architecture facilitates variations of arranging odd digit lines 118A and odd comparative digit lines 118AF enumerated, e.g., 1, 1F, 3, 3F, 5, 5F, 7, 7F . . . n+1, n+1F, and even digit lines 118B and even comparative digit lines 118BF, enumerated e.g., 0, 0F, 2, 2F, 4, 4F, 6, 6F . . . n, nF, where odd digit lines 118A, horizontally extend only from one array region 102 (e.g., the first array region 102A), at an odd digit line exit sub region 104A (e.g., the odd digit line exit sub region 104A between the first array region 102A and the fifth array region 102E), and similarly where even digit lines 118B, horizontally extend from only one array region 102 at an even digit line exit sub region 104B (e.g., the even digit line exit sub region 104B between e.g., the first array region 102A and the third array region 102C).

Referring collectively to FIGS. 2A and 3A, interconnection between the several digit lines 118 and sense amplifier circuitry of the CMOS circuitry sub region SA sections 240 include redistribution levels that route interconnections in an X-Y plane, and contacts that vertically route interconnections in the Z-direction. A first redistribution structure pad 299 (FIG. 3A) may include first contact pads 299 (FIG. 3A) horizontally positioned where digit lines 118 horizontally terminate within the digit line exit regions 104. The digit lines 118 may be coupled to the contact pads 299 (FIG. 3A). Digit line interconnects 298D vertically extend between and couple the first contact pads 299 (KO) to second contact pads 301 vertically overlying the first contact pads 299 (KO). The second contact pads 301 are further coupled to sense amplifiers of the CMOS circuitry sub region SA section 240 by way of lateral interconnect 303 (FIG. 3A) horizontally extending within and from the digit line exit regions 104 into the CMOS circuitry sub region SA section 240 (FIG. 3A). Greater detail for the digit line interconnects 298D is set forth below in relation to the odd digit line lines 118A and the odd comparative digit lines 118AF; and to the even digit lines 118B and the even comparative digit lines 118BF. Odd digit line interconnects 298D coupling the first odd comparative digit lines 118A1 and 118A1F may be further defined as respective first odd digit line interconnects 298DLA1 and first odd comparative digit line interconnects 298DLA1F. Odd digit line interconnects 298D coupling third odd comparative digit lines 118A3 and 118A3F may be further defined as respective third odd digit line interconnects 298DLA3 and third odd comparative digit line interconnects 298DLA3F. Odd digit line interconnects 298D coupling fifth odd digit lines 118A5 and 118A5F may be further defined as respective fifth odd digit line interconnects 298DLA5 and fifth odd comparative digit line interconnects 298DLA5F. Odd digit line interconnects 298D coupling n+1^{st} odd digit lines 118An+1 and 118An+1F may be further defined as respective n+1^{st} odd digit line interconnects 298DLAn+1 and n+1^{st} odd comparative digit line interconnects 298DLAn+1F. Similarly, even digit line interconnects 298D coupling zeroth comparative even digit lines 118B0 and 118B0F may be further defined as respective zeroth even digit line interconnects 298DLB0 and zeroth even comparative digit line interconnects 298DLBOF. Even digit line interconnects 298D coupling second comparative even digit lines 118B2 and 118B2F may be further defined as respective second even digit line interconnects 298DLB2 and second even comparative digit line interconnects 298DLB2F. Even digit line interconnects 298D coupling fourth even digit lines 118A4 and 118A5F may be further defined as respective fourth even digit line interconnects 298DLB4 and fourth even comparative digit line interconnects 298DLB4F. Even digit line interconnects 298D coupling n^{th} even digit lines 118Bn and 118nF may be further defined as respective n^{th} even digit line interconnects 298DLBn and n^{th} even comparative digit line interconnects 298DLBnF.

Referring to FIG. 2A, the word lines 120 include odd word lines 120A, even word lines 120B, and electrically inactive word lines 120D (also referred to as “dummy” word lines 120D). The electrically inactive word lines 120D may be located adjacent and proximate digit line exit regions 104, such that the CMOS circuitry sub region SA sections 240 may horizontally overlap the electrically inactive word lines 120D. In an embodiment, sense amplifiers within an individual odd sense amplifier sub section 240A vertically overlie and horizontally overlap electrically inactive word lines 120D within an individual array region 102 (e.g., the first array region 102A). Similarly, in an embodiment, sense amplifiers within an individual even sense amplifier sub section 240B vertically overlie and horizontally overlap electrically inactive word lines 120D within an individual array region 102 (e.g., the first array region 102A).

Referring to FIG. 2B, which is a simplified plan view providing further detail with respect to different features of the microelectronic device 101, an individual odd sense amplifier sub section 240A may include complementary metal-oxide-semiconductor (CMOS) logic circuitry sub regions individually including N sense amplifier (NSA) sub sections 240N including NSA circuitry, P sense amplifier (PSA) sub sections 240P including PSA circuitry, equalization (EQ) amplifier sub sections 240EQ horizontally interposed between the NSA sub sections 240N and the PSA sub sections 240P and including EQ amplifier sub sections 240EQ, and column-select (CS) sub sections 240CS neighboring sides of the NSA sub sections 240N and the PSA sub sections 240P opposite the EQ amplifier sub sections 240EQ and including CS sub sections 240CS. Paired digit lines 118 (e.g., the first odd digit line 118A1 and the first odd comparative digit line 118A1F) may individually be coupled by way of digit line interconnects 298D to an individual CMOS circuitry sub region. For example, the first odd digit line 118A1 and the first odd comparative digit line 118A1F are paired to CMOS logic circuitry of a first sense amplifier sub section 240A1. The several CMOS logic circuitry sub regions in an individual odd sense amplifier sub section 240A may include up to n+1 odd CMOS logic circuitry sub region SA sub sections 240An+1, where the n+1^{st} odd digit line 118An+1 and the comparative n+1^{st} digit line 118An+1F are coupled at least to the n+1^{st} sense amplifier circuitry of the CMOS logic circuitry of an individual odd CMOS logic circuitry sub region 240An+1. In addition, in an embodiment, each even digit line and comparative even digit line is coupled at least to sense amplifier circuitry of the CMOS logic circuitry of an individual CMOS logic circuitry sub region. For example, the zeroth even digit line 118B0 and the zeroth comparative even digit line 118B0F may be paired to CMOS logic circuitry of a zeroth sense amplifier sub section 240B0. The several CMOS circuitry sub regions 240 in an individual even sense amplifier sub section 240B may include up to n even CMOS logic circuitry SA sub sections 240Bn, where the n^{th} even digit line 118Bn and the comparative n^{th} even digit line 118BnF are coupled at least to the n^{th} sense amplifier circuitry of the CMOS logic circuitry of an individual even CMOS logic circuitry SA sub section 240Bn. For each of the odd sense amplifier sub sections, orientation of the CMOS circuitry sub region SA sections 240 may include the NSA sub sections 240N and the PSA sub sections 240P in reversed linear order to that illustrated in FIG. 2B, depending upon useful circuitry configurations. For the first array region 102A, an individual NSA sub section 240N may be primarily within a horizontal area of the odd digit line exit sub regions 104A or 104B, and an individual PSA sub section 240P may be primarily within the horizontal area of the first array region 102A.

Still referring to FIG. 2B, each SWD section 242 may include word line coupling regions that horizontally neighbor the word line exit regions 106 (e.g., FIG. 1) within the memory array device assembly (e.g., FIGS. 3A and 3B). Each sub word line driver section 242 may also include main word line driver (MWD) circuitry and sub word line driver (SWD) circuitry. Within the CMOS device structure 218 and at or proximate a horizontal center of an individual array region 102, a sense amplifier control-signal conduit 270 may be located to couple with the sense amplifier circuitry of the CMOS circuitry sub region SA sections 240 horizontally overlapping the array region 102. Other control logic devices 191 included within the CMOS device structure 218 may include, without limitation, SWD assist circuitry 243, such as FX drivers 243FX and row fuse match/latch word line decoders 243RD (RPDEC). In addition, further regions may be include within the CMOS device structure 218, and may include, without limitation, column decoder circuitry and gaps 241 (e.g., spaces) for various routing structures.

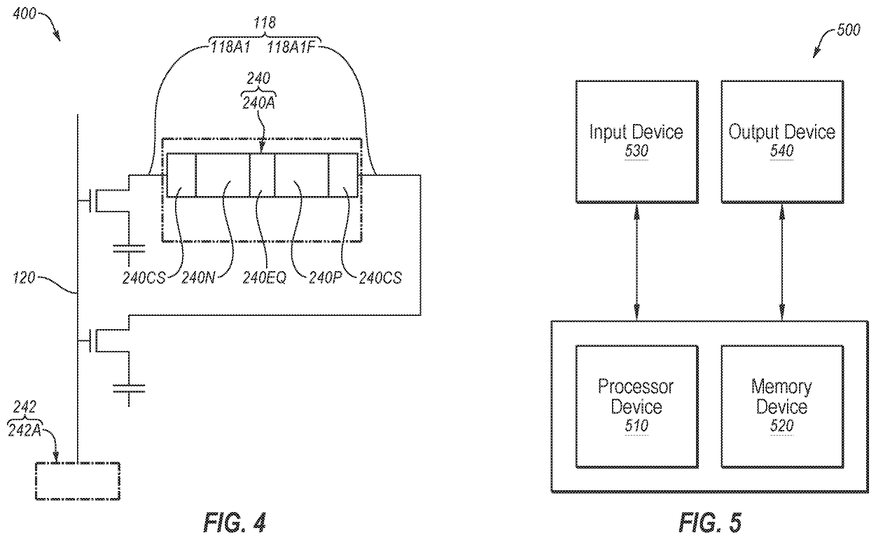

Referring collectively to FIGS. 1, 3A, and 3B, the arrays of memory cells 146 of the first microelectronic device structure assembly 156 are positioned within the horizontal areas of the array regions 102 of the microelectronic device 101. In FIG. 3A the first array region 102A is illustrated, as well as the odd digit line exit sub region 104A positioned between the first array region 102A and the fifth array region 102E (FIG. 1). As shown in FIG. 3A, control logic circuitry (e.g., CMOS logic circuitry) within the CMOS device structure 218 may be configured to read data obtained from the digit lines 118 by use of a two-transistor, two capacitor (2T-2C) configuration. The 2T-2C configuration may, for example, exhibit the configuration shown in FIG. 4 (described in further detail below).

As depicted in FIG. 3A and previously described herein, the odd SA sub sections 240A of the second microelectronic device structure assembly 218 may be positioned with horizontal area of odd digit line exit sub region 104A of the microelectronic device 101. One such odd digit line exit sub region 104A is illustrated in FIG. 3A, and may be horizontally interposed between the first array region 102A and the fifth array region 102E (FIG. 1), as seen taken from a section A depicted in FIG. 1. Within the first microelectronic device structure assembly 156 of the microelectronic device 101, a first odd digit line 118A1 and a first odd comparative digit line 118A1F may horizontally extend (e.g., in the Y-direction) through the first array region 102A into the odd digit line exit sub region 104A. Termination points of the odd digit line 118A within the first microelectronic device assembly 156 may be within a horizontal area of the odd SA sub section 240A of the second microelectronic device structure assembly 218. Additionally, conductive structures (e.g., conductive contacts, conductive routing, conductive pads) coupling the odd digit lines 118A to sense amplifier circuitry within the odd SA sub section 240A may be confined within the horizontal area of the odd SA sub section 240A. The odd digit line exit sub region 104A may be referred to as being located at a first lateral feature of, e.g., the first array region 102A, and the even digit line exit sub region 104B (FIG. 1) may be referred to as being located at a second lateral feature of, e.g., the first array region 102A, where the even digit line exit sub region 104B is diagonally across from and opposite and odd digit line exit sub region 104A. Similarly to odd digit line termination points within odd digit line exit sub region 104A, termination points of even digit lines 118B within the first microelectronic device assembly 156, may be within a horizontal area of the even SA sub sections 240B (FIG. 1) of the second microelectronic device structure assembly 218.

Still referring to FIG. 3A, digit lines 118, such as the first odd digit lines 118A1 and the first odd comparative digit lines 118A1L, are operatively associated with access devices 116 (e.g., access transistors) of the memory cells 146 located within the first microelectronic device structure assembly 156. The access devices 116 may be positioned within the horizontal area of array regions 102 (e.g., the first array region 102A). As shown in FIG. 3A, the first odd digit lines 118A1 may individually extend laterally (Y-direction) farther into an individual odd digit line exit region 104 than individual first odd comparative digit lines 118A1F with they are paired, or vice versa.

Each access device 116 may individually include a channel region comprising a portion of the base semiconductor structure 110; a source region and a drain region each individually comprising one or more of at least one conductively doped portion of the base semiconductor structure 110 and/or at least one conductive structure formed in, on, or over the base semiconductor structure 110; and at least one gate structure comprising a portion of at least one of the word lines 120. Each access device 116 may also include a gate dielectric material (e.g., a dielectric oxide material) formed to be interposed between the channel region thereof and the gate structure thereof. Within the array region 102, additional features (e.g., structures, materials) are also located on, over, and/or between the access devices 116, the digit lines 118, and the word lines 120. For example, as shown in FIG. 3A, first contact structures 122 (e.g., digit line contact structures, also referred to as so-called “bitcon” structures) may be configured to vertically extend between and couple the access devices 116 to the digit lines 118; second contact structures 124 (e.g., cell contact structures, also referred to as so-called “cellcon” structures) may be configured in contact with the access devices 116 and may configured and positioned to couple the access devices 116 to subsequently formed storage node devices (e.g., capacitors); dielectric cap structures 126 may be configured on or over the digit lines 118; and additional dielectric cap structures 128 may be configured on or over the word lines 120. In addition, dielectric structures (e.g., dielectric spacers, such as low-k dielectric spacers formed of and including one or more low-k dielectric materials) may be configured to intervene (e.g., horizontally intervene) between and isolate the second contact structures 124 and digit lines 118; and further dielectric structures (e.g., gate dielectric structures, such as gate dielectric oxide structures) may be configured to intervene (e.g., horizontally intervene) between and isolate the first contact structures 122 and the word lines 120.

The first contact structures 122 and the second contact structures 124 may individually include at least one conductive material. In some embodiments, the first contact structures 122 and the second contact structures 124 individually include one or more of at least one metal (e.g., W), at least one alloy, at least one conductive metal silicide (e.g., one or more of titanium silicide (TiSiₓ), cobalt silicide (CoSiₓ), tungsten silicide (WSiₓ), tantalum silicide (TaSiₓ), molybdenum silicide (MoSiₓ), and nickel silicide (NiSiₓ)), and at least one conductive metal nitride (e.g., one or more of TiN_{y}, tungsten nitride (WN_{y}), tantalum nitride (TaN_{y}), cobalt nitride (CoN_{y}), molybdenum nitride (MoN_{y}), and nickel nitride (NiN_{y})). In addition, the dielectric cap structures 126 and the additional dielectric cap structures 128 may individually include at least one insulative material. In some embodiments, the dielectric cap structures 126 and the additional dielectric cap structures 128 are individually formed of and include a dielectric nitride material (e.g., SiN_{y}, such as Si₃N₄).

As shown in FIG. 3A, within horizontal areas of the array regions 102 (e.g., the first array region 102A), at least one first routing tier 134 including first routing structures 136 may be located over the access devices 116; and the storage node devices 138 (e.g., capacitors) may be located over and in electrical communication with at least some of the first routing structures 136; and a second routing tier 142 including second routing structures 144 may be located over the storage node devices 138.

The first routing structures 136 of the first routing tier 134 may be employed to facilitate electrical communication between additional features (e.g., structures, materials, devices) coupled thereto. In some embodiments, at least some of the first routing structures 136 couple the access devices 116 to the storage node devices 138 to form the memory cells 146. The first routing structures 136 may serve as redistribution structures to operatively connect an array of the access devices 116 having a first layout configuration to an array of the storage node devices 138 having a second, different layout configuration. The first routing structures 136 may each individually include conductive material. By way of non-limiting example, the first routing structures 136 may include one or more of at least one metal, at least one alloy, and at least one conductive metal-containing material (e.g., a conductive metal nitride, a conductive metal silicide, a conductive metal carbide, a conductive metal oxide). In some embodiments, the first routing structures 136 are formed of and include tungsten (W).

Still referring to FIG. 3A, at least some of the digit lines 118 horizontally extending, in the Y-direction, through the array regions 102 may horizontally terminate (e.g., end) in the Y-direction within the odd digit line exit sub region 104A. A portion of one of the array regions 102, the first array region 102A, is illustrated to show the continuity of one of the digit lines 118 from one of array regions 102 into one of the digit line exit regions 104. Some of the digit lines 118 horizontally terminating within the digit line exit region 104 may be formed to terminate at a different horizontal position in the Y-direction within the digit line exit region 104 than some other of the digit lines 118 horizontally terminating within the digit line exit region 104. For example, an individual pair of the digit lines 118A1 and 118A1F horizontally extending through the array region 102 (FIG. 1A) and horizontally terminating within an individual digit line exit region 104 may be configured to terminate at substantially staggered horizontal positions relative to one another in the Y-direction. In some embodiments, at least some digit lines 118 horizontally neighboring one another in the X-direction, have terminal ends (e.g., terminal surfaces) horizontally offset from one another in the Y-direction. In an embodiment, an individual first odd digit line 118A1 has a terminal end in the Y-direction that is horizontally offset from the terminal end of an individual first odd comparative digit line 118A1L paired therewith. Horizontally offsetting the terminal ends of some of the digit lines 118 from the terminal ends of some other of the digit lines 118 within the digit line exit regions 104 may, for example, promote or facilitate desirable contact structure arrangements within the digit line exit regions 104.

Still referring to FIG. 3A, within the first microelectronic device structure assembly 156, interconnection of the digit lines 118 to the CMOS circuitry sub region sense amplifier sections 240, includes first digit line interconnects 298D (FIGS. 2A and 2B). The first digit line interconnects 298D may also be referred to as a first “vertical digit line contacts” (VDLCON) 298D. The vertical digit line contact 298D may contact (e.g., physically contact, electrically contact) conductive structures within the second routing tier 142, such as intermediate contact pads 143, that may positioned at the vertical positions (and may be fabricated at the same time as) as the second routing structures 144 within horizontal areas of the digit line exit regions 104. The intermediate contact pads 143 may be omitted in some processing embodiments, and the vertical digit line interconnects 298D may extend between the first contact pads 299 and the second contact pads 301. In an embodiment, the first digit line interconnects 298D are individually substantially monolithic (e.g., unitary) and vertically extend (e.g., in the Z-direction) at least between the digit lines 118 and the second routing tier 142. In an embodiment, one or more of the first digit line interconnects 298D vertically extend into the digit lines 118, such that the first contact pad 299 are omitted. In an embodiment, a vertical height of the first digit line interconnects 298D is greater that a combined vertical height of the first routing structures 136 and the storage node devices 138. In an embodiment, the first digit line interconnects 298D in FIG. 3A are illustrated within the section A in FIG. 1, and are also illustrated in FIG. 2A as the first odd digit line interconnect 298DLA1 and the first odd comparative digit line interconnect 298DLAIF. Further interconnection features coupling the digit lines 118 to the sense amplifier circuitry within the CMOS circuitry sub region SA sections 240 include the second contact pads 301. The second contact pads 301 may be positioned at an interface between the first microelectronic device structure assembly 156 and the second microelectronic device structure 218. Processing to form the microelectronic device 101 may include, in part, oxide-oxide bonding of oxide material 164 of the first microelectronic device structure assembly 156 to additional oxide material 226 of the second microelectronic device structure 218.

Still referring to FIG. 3A, lateral interconnects 303 within the second microelectronic device structure 218 may couple the digit lines 118 with sense amplifier circuitry of the CMOS circuitry sub region SA sections 240. Impedance matching may be done by approximating overall connection lengths between a storage node device and sense amplifier circuitry of the CMOS circuitry sub region SA sections 240. Several lateral-interconnect distance totals between an individual first odd digit line 118A1 sense amplifier circuitry of an individual odd sense amplifier sub section 240A operatively associated therewith may include a first length R within the first odd digit line 118A1 from a given first contact structure 122′, and a second length S of a lateral interconnect 303 that completes coupling the first odd digit line 118A1 to the sense amplifier circuitry the odd sense amplifier sub section 240A. Several lateral-interconnect distance totals between an individual first odd comparative digit line 118A1L and the sense amplifier circuitry of the odd sense amplifier sub section 240A may include a third length T within the first odd comparative digit line 118A1L from the given first contact structure 122′, and a fourth length U of an individual lateral interconnect 303 that facilitates coupling the first odd comparative digit line 118A1L to the sense amplifier circuitry of the first odd sense amplifier subsection 240A. In an embodiment, the lengths R+S equal the lengths T+U within useful tolerances where impedance matching may be further tuned according to useful techniques. In an embodiment, the first and second lengths R+S are substantially equal to the third and fourth lengths T+U. In an embodiment, the first and second lengths R+S are electronically signal-carrying equal lengths to the third and fourth lengths T+U.

The lateral interconnects 303 within the second microelectronic device structure assembly 218 may be part of an additional routing tier 196. In addition, the second microelectronic device structure assembly 218 may further include additional routing structures 198 vertically overlying and operatively associated with one or more of control logic circuitry (e.g., CMOS logic circuitry) within the second microelectronic device structure assembly 218 and the memory cells 146 within the first microelectronic device structure assembly 156. At least some of the additional routing structures 198 may be configured and positioned as coupling features (e.g., structures, devices) to electrically connect other features of the microelectronic device 101 to back-end-of-line (BEOL) contact structures 202. The BEOL contact structures 202 and the additional routing structures 198, for example, couple external circuitry (e.g., global circuitry) of a relatively larger device including the microelectronic device 101 to internal circuitry (e.g., local circuitry) of the microelectronic device 101.

Within the digit line exit region 104, electrically inactive word lines 121 may, optionally, be located vertically below the digit lines 118. If so located, the electrically inactive word lines 121 may be located at substantially the same vertical position (e.g., vertical elevation) within the microelectronic device 101 (e.g., within the base semiconductor structure 110 thereof) as the word lines 120, and may be located to horizontally extend orthogonal to the digit lines 118 (e.g., in the X-direction). A material composition of the electrically inactive word lines 121 may be substantially the same as a material composition of the word lines 120. The electrically inactive word lines 121 may be electrically isolated from one another and the other components (e.g., the word lines 120, the digit lines 118) of the microelectronic device 101. The electrically inactive word lines 121 (if any) within the digit line exit region 104 may not be part of data paths during use and operation of the microelectronic device 101 of the disclosure. In additional embodiments, the electrically inactive word lines 121 are absent (e.g., omitted) from the digit line exit region 104.

Referring to FIG. 3B, within the word line exit regions 106 at least some of the word lines 120 horizontally extending, in the X-direction, through the array regions 102 may horizontally terminate (e.g., end) in the X-direction. Portions of two of the array regions 102, the first array region 102A and the second array region 102B, are illustrated in FIG. 3B and may be located within a section B in FIG. 1. FIG. 3B illustrates the continuity of one of the word lines 120, an odd word line 120A, from one of the array regions 102 into one of the word line exit regions 106. As shown in FIG. 3B, one of the SWD sections 242 of the second microelectronic device structure assembly 218 is positioned above the memory cells 146 within the second array region 102B and horizontally overlaps (e.g., in the X-direction) the second array region 102B. The SWD section 242 may also horizontally overlap one of the word line exit regions 106 (e.g., the odd word line exit region 106A).

As shown in FIG. 3B, sub-word line drivers of the SWD sections 242 and conductive structures coupling the word lines 120 to the sub-word line drivers of the SWD sections 242 may be substantially confined within horizontal boundaries of the array regions 102. In an embodiment, within an individual word line exit region 106, a first redistribution structure pad 299 may be part of the first routing tier 134 and the first redistribution structure pad 299 is coupled to an individual word line 120 by way of a first contact 295. In addition, the first redistribution structure pad 299 may be coupled to a second contact pad 301 by way of a first word line interconnect 298WL. The first word line interconnect 298WL may also be referred to as a first “vertical word line contact” (VWLCON) 298WL. In addition, the second contact pad 301 may at least partially vertically overlie and be coupled to the second contact pad 299. The second contact pad 301 may also be coupled to sub-word line driver circuitry with the SWD section 242. The second contact pad 301 may be positioned at an interface of the isolation structure 234 formed from an oxide material 164 of the first microelectronic device structure assembly 156 and an oxide material 226 of the second microelectronic device structure 218.

FIG. 4 is a schematic diagram 400 of connections between a word line 120 and digit lines 118 that includes a sense amplifier sub section 240A (odd SA sub section 240A) in a two-transistor, two capacitor (2T-2C) configuration. A word line 120 is coupled to an odd sub word line driver 242A, and first odd digit line 118A1 and first odd comparative digit line 118A1F are coupled to the odd sense amplifier sub section 240A.

Microelectronic devices (e.g., the microelectronic device 101) of the disclosure may be included in embodiments of electronic systems of the disclosure. For example, FIG. 5 is a block diagram of an electronic system 500, according to embodiments of disclosure. The electronic system 500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, or a navigation device, etc. The electronic system 500 includes at least one memory device 520. The memory device 520 may include, for example, one or more of the microelectronic devices (e.g., the microelectronic device 101) of the disclosure. The electronic system 500 may further include at least one electronic signal processor device 510 (often referred to as a “microprocessor”) that is part of an integrated circuit. The electronic signal processor device 510 may include, for example, one or more of microelectronic devices (e.g., the microelectronic device 101) of the disclosure. While the memory device 520 and the electronic signal processor device 510 are depicted as two (2) separate devices in FIG. 5, in additional embodiments, a single (e.g., only one) memory/processor device having the functionalities of the memory device 520 and the electronic signal processor device 510 is included in the electronic system 500. In such embodiments, the memory/processor device may include, for example, one or more of the microelectronic devices (e.g., the microelectronic device 101) of the disclosure. The electronic signal processor device 510 and the memory device 520 may be part of a disaggregated-die assembly 510 and 520.

The electronic system 500 may further include one or more input devices 530 for inputting information into the electronic system 500 by a user, such as, for example, a mouse or other pointing device, a keyboard, a touchpad, a button, or a control panel. The electronic system 500 may further include one or more output devices 540 for outputting information (e.g., visual or audio output) to a user such as, for example, a monitor, a display, a printer, an audio output jack, and/or a speaker. In some embodiments, the input device 530 and the output device 540 may comprise a single touchscreen device that can be used both to input information to the electronic system 500 and to output visual information to a user. The input device 530 and the output device 540 may communicate electrically with one or more of the memory device 520 and the electronic signal processor device 510.

Thus, disclosed is a microelectronic device, comprising: array regions individually comprising: memory cells comprising access devices and storage node devices; digit lines coupled to the access devices and extending in a first direction; and word lines coupled to the access devices and extending in a second direction orthogonal to the first direction; digit line exit regions horizontally alternating with the array regions in the first direction; sense amplifier sections comprising sense amplifier circuitry vertically overlying and horizontally overlapping the digit line exit regions; and routing structures within horizontal areas of the digit line exit regions and coupling the sense amplifier circuitry of the sense amplifier sections to the digit lines.

Also disclosed is a first microelectronic device structure comprising array regions comprising memory cells; digit line exit regions neighboring the array regions in a first horizontal direction; word line exit regions neighboring the array regions in a second horizontal direction perpendicular to the first horizontal direction; digit lines coupled to the memory cells of the array regions and terminating in the first horizontal direction within the digit line exit regions; and word lines coupled to the memory cells of the array regions and terminating in the second horizontal direction within the word line exit regions; and a second microelectronic device structure vertically overlying the first microelectronic device structure and comprising: sense amplifier (SA) regions at least partially horizontally overlapping the digit line exit regions and comprising SA circuitry coupled to the digit lines; and sub-word line driver (SWD) regions horizontally offset from the SA regions and comprising SWD circuitry coupled to the word lines.

Also disclosed is an electronic system, comprising: an input device; an output device; a processor device operably coupled to the input device and the output device; and a memory device operably coupled to the processor device and comprising at least one microelectronic device structure comprising: array regions individually comprising: an array of memory cells; digit lines coupled to the array of memory cells; comparative digit lines paired with the digit lines and coupled to the array of memory cells; and word lines coupled to the array of memory cells access devices and horizontal extending orthogonal to the digit lines and the comparative digit lines; digit line exit regions alternating with the array regions in a first horizontal direction, horizontal ends of the digit lines and the comparative digit lines terminating within the digit line exit regions; word line exit regions alternating with the array regions in a second horizontal direction, horizontal ends of the word lines terminating within the word line exit regions; and sense amplifier sections comprising sense amplifier circuitry vertically overlying and horizontally overlapping the digit line exit regions, the sense amplifier circuitry in electrical communication with the digit lines and the comparative digit lines, and each array region is configured with an odd sense amplifier section proximate a first corner of the array section, and with an even sense amplifier section proximate a fourth corner of the array section that is diagonally across from the first corner.

The structures, devices, system, and methods of the disclosure advantageously facilitate one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
array regions individually comprising:
memory cells comprising access devices and storage node devices;
digit lines coupled to the access devices and extending in a first direction; and
word lines coupled to the access devices and extending in a second direction orthogonal to the first direction;
digit line exit regions horizontally alternating with the array regions in the first direction;
sense amplifier sections comprising sense amplifier circuitry vertically overlying and horizontally overlapping the digit line exit regions; and
routing structures within horizontal areas of the digit line exit regions and coupling the sense amplifier circuitry of the sense amplifier sections to the digit lines.

2. The microelectronic device of claim 1, wherein the routing structures comprise:
vertical routing structures within the horizontal areas of the digit line exit regions and vertically extending between the sense amplifier circuitry and ends of some of the digit lines within the digit line exit regions;
horizontal routing structures confined within the horizontal areas of the digit line exit regions and extending between the sense amplifier circuitry and some of the vertical routing structures; and
additional horizontal routing structures within the horizontal areas of the digit line exit regions and horizontal areas of the array regions, the additional horizontal routing structures extending between the sense amplifier circuitry and some other of the vertical routing structures.

3. The microelectronic device of claim 1, wherein the sense amplifier sections comprise:
odd sense amplifier sections proximate corners of the array regions; and
even sense amplifier sections proximate additional corners of the array regions that is diagonally opposing the corners of the array regions.

4. The microelectronic device of claim 3, wherein the digit line exit regions comprise:
odd digit line exit sub-regions vertically underlying and horizontally overlapping the odd sense amplifier sections; and
even digit line exit sub-regions vertically underlying and horizontally overlapping the even sense amplifier sections.

5. The microelectronic device of claim 1, wherein:
some of the word lines within the array regions are configured to be electrically inactive and are horizontally interposed between the sense amplifier sections; and
some other of the word lines within the array regions are configured to be electrically active.

6. The microelectronic device of claim 1, wherein the sense amplifier circuitry of at least one sense amplifier section comprises:
a first portion horizontally overlapping one of the digit line exit regions; and
a second portion horizontally overlapping one of the array regions horizontally neighboring the one of the digit line exit regions.

7. The microelectronic device of claim 1, wherein the sense amplifier circuitry of the sense amplifier sections comprises complementary metal-oxide-semiconductor (CMOS) circuitry.

8. The microelectronic device of claim 7, wherein the sense amplifier circuitry of the sense amplifier sections comprise:
PMOS sense amplifier circuitry coupled to first conductive contacts within the digit line exit regions; and
NMOS sense amplifier circuitry coupled to second conductive contacts within the digit line exit regions.

9. The microelectronic device of claim 8, wherein the sense amplifier sections further comprise:
equalization amplifier circuitry horizontally interposed between the PMOS sense amplifier circuitry and the NMOS sense amplifier circuitry; and
column select circuitry horizontally neighboring the PMOS sense amplifier circuitry and the NMOS sense amplifier circuitry.

10. The microelectronic device of claim 1, wherein the digit lines comprise:
first digit lines coupled to the sense amplifier circuitry of the sense amplifier sections by way of portions of the routing structures extending to first horizontal boundaries of the sense amplifier sections; and
second digit lines coupled to the sense amplifier circuitry of the sense amplifier sections by way of additional portions of the routing structures extending to second horizontal boundaries of the sense amplifier sections opposing the first horizontal boundaries.

11. The microelectronic device of claim 10, wherein, within the digit line exit regions, ends of the first digit lines in the first direction are horizontally offset from ends of the second digit lines in the first direction.

12. The microelectronic device of claim 1, wherein the routing structures comprise:
first conductive contact pads coupled to the digit lines within the digit line exit regions;
first conductive contacts on the first conductive contact pads; and
second conductive contact pads coupled to the first conductive contacts and the sense amplifier circuitry, the second conductive contact pads at least partially within the horizontal areas of the digit line exit regions.

13. The microelectronic device of claim 1, wherein the memory cells of the array regions comprise dynamic random access memory (DRAM) cells.

14. The microelectronic device of claim 1, wherein:
the access devices of the memory cells vertically underlie the storage node devices of the memory cells; and
the word lines vertically underlie the digit lines.

15. A microelectronic device, comprising:
a first microelectronic device structure comprising:
array regions comprising memory cells;
digit line exit regions neighboring the array regions in a first horizontal direction;
word line exit regions neighboring the array regions in a second horizontal direction perpendicular to the first horizontal direction;
digit lines coupled to the memory cells of the array regions and terminating in the first horizontal direction within the digit line exit regions; and
word lines coupled to the memory cells of the array regions and terminating in the second horizontal direction within the word line exit regions; and
a second microelectronic device structure vertically overlying the first microelectronic device structure and comprising:
sense amplifier (SA) regions at least partially horizontally overlapping the digit line exit regions and comprising SA circuitry coupled to the digit lines; and
sub word line driver (SWD) regions horizontally offset from the SA regions and comprising SWD circuitry coupled to the word lines.

16. The microelectronic device of claim 15, wherein the SA regions of the second microelectronic device structure partially horizontally overlap digit line exit regions of the first microelectronic device structure and partially horizontally overlap the array regions of the first microelectronic device structure.

17. The microelectronic device of claim 16, wherein the SA circuitry of at least one of the SA regions comprises:
NMOS sense amplifier circuitry horizontally overlapping one of the digit line exit regions of the first microelectronic device structure; and
PMOS sense amplifier circuitry horizontally overlapping one of the array regions of the first microelectronic device structure.

18. The microelectronic device of claim 17, wherein the SA circuitry of the at least one of the SA regions further comprises equalization (EQ) amplifier circuitry interposed between the NMOS sense amplifier circuitry and the PMOS sense amplifier circuitry in the first horizontal direction.

19. The microelectronic device of claim 18, wherein the at least one of the SA regions further comprises:
column select circuitry neighboring the NMOS sense amplifier circuitry in the first horizontal direction and horizontally overlapping the one of the digit line exit regions of the first microelectronic device structure; and
additional column select circuitry neighboring the PMOS sense amplifier circuitry in the first horizontal direction and horizontally overlapping the one of the array regions of the first microelectronic device structure.

20. An electronic system, comprising:
an input device;
an output device;
a processor device operably coupled to the input device and the output device; and
a memory device operably coupled to the processor device and comprising at least one microelectronic device structure comprising:
array regions individually comprising:
an array of memory cells;
digit lines coupled to the array of memory cells;
comparative digit lines paired with the digit lines and coupled to the array of memory cells; and
word lines coupled to the array of memory cells access devices and horizontally extending orthogonal to the digit lines and the comparative digit lines;
digit line exit regions alternating with the array regions in a first horizontal direction, horizontal ends of the digit lines and the comparative digit lines terminating within the digit line exit regions;
word line exit regions alternating with the array regions in a second horizontal direction, horizontal ends of the word lines terminating within the word line exit regions; and sense amplifier sections comprising sense amplifier circuitry vertically overlying and horizontally overlapping the digit line exit regions, the sense amplifier circuitry in electrical communication with the digit lines and the comparative digit lines; and
each array region is configured with an odd sense amplifier section proximate a first corner of the array region, and with an even sense amplifier section proximate a fourth corner of the array region that is diagonally across from the first corner.

21. The electronic system of claim 20, further comprising routing structure within horizontal areas of the digit line exit regions and coupling the sense amplifier circuitry of the sense amplifier sections to the digit lines and the comparative digit lines.

22. The electronic system of claim 20, wherein the sense amplifier sections only partially horizontally overlap the digit line exit regions.

23. The electronic system of claim 20, further comprising sub-word line driver sections horizontally offset from the sense amplifier sections and comprising sub-word line driver circuitry at a vertical position of the sense amplifier circuitry, the sub-word line driver circuitry in electrical communication with word lines.

24. The electronic system of claim 20, wherein the memory device comprises a DRAM device.
